(19) United States
(12) Patent Application Publication
(10) Pub. No.: US 2025/0279287 A1
(43) Pub. Date: Sep. 4, 2025

(54) METAL OXIDE FILM AND METAL FILM LINER COMBINATION IN A SEMICONDUCTOR STRUCTURE, RELATED DEVICES, RELATED SYSTEMS, AND RELATED METHODS

(71) Applicant: ASM IP Holding B.V., Almere (NL)

(72) Inventors: Hameeda Jagalur Basheer, Leuven (BE); Vivek Koladi Mootheri, Leuven (BE); Andrea Illiberi, Leuven (BE); Michael Eugene Givens, Scottsdale, AZ (US); Junghoon Lee, Seoul (KR); Jerome Innocent, Bristol (GB); Aditya Chauhan, Ottignies-Louvain-la-Neuve (BE); Suvidyakumar Vinod Homkar, Leuven (BE)

(21) Appl. No.: 19/064,452

(22) Filed: Feb. 26, 2025

Related U.S. Application Data
(60) Provisional application No. 63/559,573, filed on Feb. 29, 2024.

(51) Int. Cl. H01L 21/443; H10D 62/80; H10D 64/01; H10D 64/68

(52) U.S. Cl. CPC H01L 21/443; H10D 62/875; H10D 64/01; H10D 64/691

(57) ABSTRACT

The present disclosure generally relates to the field of semiconductor devices. More particularly, it relates to a method for producing an electrode contact layer comprising a metal oxide film and a metal film liner, related devices and systems for producing the same.

### CROSS-REFERENCE TO RELATED APPLICATION(S)

This Application claims the benefit of U.S. Provisional Application 63/559,573 filed on Feb. 29, 2024, the entire contents of which are incorporated herein by reference.

### FIELD OF INVENTION

The present disclosure generally relates to the field of semiconductor devices. More particularly, it relates to a method for producing an electrode contact layer comprising a metal oxide film and a metal film liner, related devices and systems for producing the same.

### BACKGROUND OF THE DISCLOSURE

Field-effect transistors (FETs) are fundamental electronic devices used to control the flow of electrical current in a circuit. In FETs, there are typically three main components: the source, the drain, and the gate. The gate controls the flow of current through a semiconductor channel arranged between the source and the drain. Importantly, when a voltage is applied to the gate, it creates an electric field that controls the flow of charge carriers (electrons or holes) within the channel layer, thus modulating the current flowing between the source and the drain, where the source serves as the entry point for these charge carriers, and the drain acts as the exit point.

While FETs have undergone significant advancements, challenges remain in optimizing their performance. One important aspect is the contact resistance between the electrodes (source and drain) and the semiconductor channel. The selection of suitable materials for electrodes and the semiconductor channel is pivotal. For instance, formation of unwanted barriers at the interface between metal electrodes and the semiconductor channel or an increased surface roughness may significantly hinder the efficient flow of charge carriers, leading to a higher contact resistance. In addition, increased miniaturization of electronic devices further poses significant challenges in maintaining low contact resistance to ensure high transistor performance.

In view of the above, a need exists to remedy the aforementioned drawbacks in FET design, preferably without reducing their stability and high threshold voltage, which is necessary for the development of commercially relevant and reliable FETs.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In general, the technology disclosed herein relates to the field of semiconductor devices, and more particularly to a method for forming an electrode contact layer comprising a combination of a metal oxide film and a metal film liner during the manufacturing of semiconductor devices or related components. This method is applicable to the manufacture of semiconductor devices, including, but not limited to, field effect transistors (FETs) or memory devices incorporating one or more FETs.

In particular, deposition of a metal film on at least a part of a (previously deposited) metal oxide film generates a structure that may serve as a point of electrical contact to an electrode in a transistor. Advantageously, it has been found that the formed structure may provide a significantly reduced contact resistance and improved electrical connection between the electrode and the underlying semiconductor material compared to state-of-the-art FETs comprising (non-oxidized) metal contacts. Specifically, it has been found that the electrode contact layer comprising a metal oxide film and a metal film liner as disclosed herein may improve the ON current performance of a FET (i.e., the current that flows between the source and the drain terminals of the transistor when it is in the “ON” or conducting state), without losing the ability to conduct and perform the functionalities of conventional metal contacts. In this way, it may provide for more efficient charge carrier (electrons or holes) transport between the semiconductor and the electrode, which is important for the proper functioning of electronic devices.

Accordingly, in some broad respects, the present disclosure relates to FETs and memory devices, and methods and systems of manufacturing at least a part of said FETs and memory devices, which can be suitable as electronic components for various applications such as central processing units (CPU)s and system-on-a-chip (SoC).

An aspect of the present disclosure relates to a method for forming an electrode contact layer comprising a metal oxide film and a metal film liner. The method preferably comprises the steps of: a) providing a substrate into a reaction chamber, wherein the substrate comprises a semiconductor oxide film or a sacrificial film on at least a portion of a surface of the substrate; b) executing one or more cycles, each cycle comprising: i. a first metal precursor pulse, wherein at least a part of the semiconductor oxide film or the sacrificial film is contacted with one or more first metal precursor(s), by introducing the first metal precursor into the reaction chamber; ii. an oxygen reactant pulse, wherein at least a part of the semiconductor oxide film or the sacrificial film is contacted with one or more oxygen reactant(s), by introducing the oxygen reactant into the reaction chamber; thereby forming the metal oxide film on the semiconductor oxide film or the sacrificial film; c) executing one or more further cycles, each further cycle comprising: a second metal precursor pulse, wherein at least a part of the metal oxide film is contacted with one or more second metal precursor(s), by introducing the second metal precursor into the reaction chamber;

thereby forming the metal film on the metal oxide film; d) whereby, in the event that the substrate comprises the sacrificial film, the method further comprises the step of removing at least a part of the sacrificial film, thereby forming a cavity, and forming a semiconductor oxide film in the cavity.

In other words, the method as disclosed herein generally relates to a deposition process, wherein the metal oxide film and the metal film are grown independently during one or more cycles, respectively. This has been shown to provide the advantage that the electrode contact layer can be formed with controlled film composition and thickness with reduced defects. Hence, resulting in a more reliable manufacturing process of semiconductor devices and related components.

In particular embodiments, the method as disclosed herein provides that the semiconductor oxide film comprises a semiconductor oxide selected from the group consisting of InGaZnO, InZnO, GaZnO, Al₂O₃, Ga₂O₃, GeO₂, In₂O₃, ZnO, SnO₂, MoO₂, and mixtures thereof.

In particular embodiments, the method as disclosed herein provides that the metal oxide film comprises a metal oxide selected from the group consisting of MgO, In₂O₃, ZnO, ZnMgO, InSnO, InZnO, InMoO, V₂O₅, TiO₂, CrO₂, MnO, FeO, Fe₂O₃, CoO, NiO, Cu₂O, CuO, ZnO, ZrO₂, NbO, NbO₂, TcO₂, RuO₂, Rh₂O₃, Ag₂O, CdO, HfO₂, HfZrO, Ta₂O₅, W₂O₃, ReO₃, OsO₄, IrO₂, PtO₂, Au₂O₃, As₂O₃, Sb₂O₃, Bi₂O₃, and mixtures thereof.

In particular embodiments, the method as disclosed herein provides that the metal film comprises one or more metal(s) or metalloid(s) with a work function of at least 4.0 eV.

In particular embodiments, the method as disclosed herein is an atomic layer deposition (ALD) method.

An overview of various other aspects of the technology of the present disclosure is provided herein below, followed by a detailed description of specific embodiments. It should be understood that the objectives and advantages mentioned above apply equally to the various other aspects and features as disclosed herein.

Another aspect of the present disclosure relates to a semiconductor device. The semiconductor device preferably comprises a substrate and at least one electrode contact layer comprising a metal oxide film and a metal film liner; wherein the metal oxide film is arranged between the substrate and the metal film.

In particular embodiments, the semiconductor device as disclosed herein provides that the metal oxide film is in direct or electrical contact with the substrate and the metal film.

Another aspect of the present disclosure relates to a field-effect transistor (FET). The FET preferably comprises: a substrate; a channel layer comprising one or more semiconductor oxide(s), preferably selected from the group consisting of InGaZnO, InZnO, GaZnO, Al₂O₃, Ga₂O₃, GeO₂, In₂O₃, ZnO, SnO₂, MoO₂, and mixtures thereof; at least one gate contact layer and at least one gate insulating layer; at least one electrode contact layer comprising a metal oxide film and a metal film liner; wherein the metal oxide film is arranged between the channel layer and the metal film.

In particular embodiments, the FET as disclosed herein provides that the ON current (Iₒₙ) of the FET is at least 50.0 μA.

Another aspect of the present disclosure relates to a system. The system preferably comprises: a reaction chamber constructed and arranged to hold a substrate comprising a semiconductor oxide film or a sacrificial film on at least a portion of a surface of the substrate; a first metal precursor vessel constructed and arranged to contain and evaporate one or more first metal precursor(s); an oxygen reactant vessel constructed and arranged to contain and evaporate one or more oxygen reactant(s); a second metal precursor vessel constructed and arranged to contain and evaporate one or more second metal precursor(s); a controller, operatively connected to the first metal precursor vessel, the oxygen reactant vessel, and the second metal precursor vessel; wherein the controller is configured to control the flow of the first metal precursor, the oxygen reactant, and the second metal precursor into the reaction chamber during one or more cycles, wherein, as a result of the cycles, a metal oxide film is formed on the semiconductor oxide film or the sacrificial film, and a metal film is formed on the metal oxide film.

In particular embodiments, the system as disclosed herein is configured to form an electrode contact layer comprising a metal oxide film and a metal film liner by means of a method as disclosed herein.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1. schematically illustrates an exemplary embodiment of a method for the manufacturing of an electrode contact layer comprising a metal oxide film and a metal film liner as disclosed herein.

FIG. 2. schematically illustrates another exemplary embodiment of a method for the manufacturing of an electrode contact layer comprising a metal oxide film and a metal film liner as disclosed herein.

FIG. 3. schematically illustrates another exemplary embodiment of a method for the manufacturing of an electrode contact layer comprising a metal oxide film and a metal film liner as disclosed herein.

FIG. 4. schematically illustrates another exemplary embodiment of a method for the manufacturing of an electrode contact layer comprising a metal oxide film and a metal film liner as disclosed herein.

FIG. 5 schematically illustrates an exemplary embodiment of a single gate field-effect transistor of the disclosure.

FIG. 6 schematically illustrates a system in accordance with yet additional exemplary embodiments of the disclosure.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims. Hence, the description below is to be regarded as illustrative in nature, and not as restrictive.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” the recited members, elements or method steps. The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). This applies to numerical ranges irrespective of whether they are introduced by the expression “from . . . to . . . ” or the expression “between . . . and . . . ” or another expression. The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, particularly a compound that constitutes a film matrix or a main skeleton of a film; the term “reactant” can be used interchangeably with the term precursor.

The term “liner” as disclosed herein generally refers to a (thin) film or layer of material that is deposited or grown on a substrate to serve a specific purpose, such as providing insulation, a diffusion barrier, or passivation. The liner (combination) as used herein may be used to engineer the interface between an electrode contact layer and a channel layer.

In the present description, technology is described that relates to the manufacturing of an electrode layer comprising a metal oxide film and a metal film liner for semiconductor devices, preferably field-effect transistors (FET)s. Extensive experimentation has demonstrated that the inclusion of a metal oxide film between the channel layer and the metal film unexpectedly provides both a decreased contact resistance (i.e., promoting the flow of charge carriers), while retaining good conductivity and a high threshold voltage.

Accordingly, an aspect of the present disclosure relates to a method for forming an electrode contact layer comprising a metal oxide film and a metal film liner. The method preferably comprises the steps of: a) providing a substrate into a reaction chamber, wherein the substrate comprises a semiconductor oxide film or a sacrificial film on at least a portion of a surface of the substrate; b) executing one or more cycles, wherein preferably each cycle comprises: i. a first metal precursor pulse, wherein at least a part of the semiconductor oxide film or the sacrificial film is contacted with one or more first metal precursor(s), by introducing the first metal precursor(s) into the reaction chamber; ii. an oxygen reactant pulse, wherein at least a part of the semiconductor oxide film or the sacrificial film is contacted with one or more oxygen reactant(s), by introducing the oxygen reactant(s) into the reaction chamber; thereby forming the metal oxide film on the semiconductor oxide film or the sacrificial film; c) executing one or more further (metal film) cycles, wherein preferably each further (metal film) cycle comprises: a second metal precursor pulse, wherein at least a part of the metal oxide film is contacted with one or more second metal precursor(s), by introducing the second metal precursor(s) into the reaction chamber; thereby forming the metal film on the metal oxide film; and, whereby, in the event that the substrate comprises the sacrificial film, the method further comprises the step of removing at least a part of the sacrificial film, thereby forming a free space or cavity, and forming a semiconductor oxide film in said free space or cavity.

The metal oxide film and metal film liner as described herein may be configured to form a contact layer, which may provide an electrical contact with the source and/or drain of a FET. Said electrode contact layer is formed or deposited by means of a method as disclosed herein over a supporting but typically non-conducting substrate. Hence, the present method starts by providing a suitable substrate to the reaction chamber.

As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can comprise a bulk material, such as silicon (e.g., single-crystal silicon), other Group IV materials, such as germanium, or other semiconductor materials, such as Group II-VI or Group Ill-V semiconductor materials, and can include one or more layers overlying or underlying the bulk material. Further, the substrate can include various features, such as recesses, protrusions, and the like formed within or on at least a portion of a layer of the substrate.

In particular embodiments, the substrate may comprise silicon, silicon germanium, silicon oxide, gallium arsenide, gallium nitride or silicon carbide (as the bulk semiconductor material). According to the present disclosure, the substrate further comprises a semiconductor oxide film or sacrificial film overlying at least a portion of the bulk semiconductor material.

A “film” or “layer” as used herein interchangeably refers to a material extending in a direction perpendicular to a thickness direction to cover an entire target or concerned surface, or simply a layer covering a target or concerned surface. In particular embodiments, a film or layer refers to a structure having a certain thickness formed on a surface or a synonym of film or a non-film structure. A layer can encompass a continuous or non-continuous structure or material, such as material deposited according to the present technology. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers.

For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may be continuous or non-continuous.

The semiconductor oxide film as described herein may form or be configured to form the channel region between the source and drain of a FET.

In particular embodiments, the semiconductor oxide film comprises a semiconductor oxide selected from the group consisting of InGaZnO (IGZO), InZnO (IZO), GaZnO (GZO), Al₂O₃, Ga₂O₃, GeO₂, In₂O₃, ZnO, SnO₂, MoO₂, and mixtures thereof.

Advantageously, it has been found that the listed semiconductor oxides may provide several improvements when applied to the channel region of FETs. For instance, it has been found that a channel region comprising the listed semiconductor oxides is characterized by a high charge carrier mobility, which enables faster transistor switching between an “ON” and “OFF” state. In addition, it has been found that said transistors can achieve a low OFF state leakage current, which is important for maintaining energy efficiency and controlling the flow of charges within advanced semiconductor devices.

In some embodiments, the semiconductor oxide may be deposited using at least one semiconductor oxide precursor, such as one or more indium precursor(s), gallium precursor(s), zinc precursor(s), aluminum precursor(s), germanium precursor(s), tin precursor(s), or molybdenum precursor(s); and one or more oxygen reactant(s). The semiconductor oxide precursor may further comprise any suitable ligand that enables fast evaporation of the semiconductor oxide precursor.

For instance, the at least one semiconductor oxide precursor may further comprise one or more halogen selected from the group consisting of fluoro (F), chloro (Cl), bromo (Br), iodo (I), and combinations thereof.

For instance, the at least one semiconductor oxide precursor may further comprise one or more alkyl. The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₂₀alkyl”, as a group or part of a group, refers to a hydrocarbyl group of formula —CₙH₂ₙ₊₁ wherein n is a number ranging from 1 to 20. Thus, for example, “C₁₋₈alkyl” includes all linear or branched alkyl groups with between 1 and 8 carbon atoms, and thus includes methyl, ethyl, n-propyl, i-propyl, butyl, and its isomers (e.g., n-butyl, i-butyl, and t-butyl); pentyl and its isomers, hexyl, and its isomers, etc. A “substituted alkyl” refers to an alkyl group substituted with one or more substituent(s) (for example 1 to 3 substituent(s), for example 1, 2, or 3 substituent(s)) at any available point of attachment.

For instance, the at least one semiconductor oxide precursor may further comprise one or more alkoxy, preferably a C₁₋₄alkoxy. The term “alkoxy” or “alkyloxy,” as a group or part of a group, refers to a group having the formula —ORC wherein RC is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

For instance, the at least one semiconductor oxide precursor may further comprise one or more cyclopentadienyls.

For instance, the at least one semiconductor oxide precursor may further comprise one or more dialkylamine (—NR^{a}R^{b}), wherein R^{a} and R^{b} are an alkyl as defined herein, preferably a C₁₋₄alkyl as defined herein.

It should be understood that within the scope of the present disclosure the semiconductor oxide precursor may comprise any combination of the aforementioned types of ligands.

In some embodiments, the at least one semiconductor oxide precursor may be selected from the group consisting of InCl₃, GaCl₃, ZnCl₂, AlCl₃, GeCl₄, SnCl₂, MoCl₄, InBr₃, GaBr₃, ZnBr₂, AlBr₃, GeBr₄, SnBr₂, MoBr₄, InI₃, GaI₃, ZnI₂, AlI₃, GeI₄, SnI₂, MoI₄, and combinations thereof.

In some embodiments, the at least one semiconductor oxide precursor may be selected from the group consisting of InMe₃, GaMe₃, ZnMe₂, AlMe₃, GeMe₄, SnMe₂, MoMe₄, InEt₃, GaEt₃, ZnEt₂, AlEt₃, GeEt₄, SnEt₂, MoEt₄, In(Prⁿ)₃, Ga(Prⁿ)₃, Zn(Prⁿ)₂, Al(Prⁿ)₃, Ge(Prⁿ)₄, Sn(Prⁿ)₂, Mo(Prⁿ)₄, In(Prⁱ)₃, Ga(Prⁱ)₃, Zn(Prⁱ)₂, Al(Prⁱ)₃, Ge(Prⁱ)₄, Sn(Prⁱ)₂, Mo(Prⁱ)₄, In(Buⁿ)₃, Ga(Buⁿ)₃, Zn(Buⁿ)₂, Al(Buⁿ)₃, Ge(Buⁿ)₄, Sn(Buⁿ)₂, Mo(Buⁿ)₄, In(Bu^{t})₃, Ga(Bu^{t})₃, Zn(Bu^{t})₂, Al(Bu^{t})₃, Ge(Bu^{t})₄, Sn(Bu^{t})₂, Mo(Bu^{t})₄, and combinations thereof.

In some embodiments, the at least one semiconductor oxide precursor may be selected from the group consisting of In(OMe)₃, Ga(OMe)₃, Zn(OMe)₂, Al(OMe)₃, Ge(OMe)₄, Sn(OMe)₂, Mo(OMe)₄, In(OEt)₃, Ga(OEt)₃, Zn(OEt)₂, Al(OEt)₃, Ge(OEt)₄, Sn(OEt)₂, Mo(OEt)₄, In(OPrⁿ)₃, Ga(OPrⁿ)₃, Zn(OPrⁿ)₂, Al(OPrⁿ)₃, Ge(OPrⁿ)₄, Sn(OPrⁿ)₂, Mo(OPrⁿ)₄, In(OPrⁱ)₃, Ga(OPrⁱ)₃, Zn(OPrⁱ)₂, Al(OPrⁱ)₃, Ge(OPrⁱ)₄, Sn(OPrⁱ)₂, Mo(OPrⁱ)₄, In(OBuⁿ)₃, Ga(OBuⁿ)₃, Zn(OBuⁿ)₂, Al(OBuⁿ)₃, Ge(OBuⁿ)₄, Sn(OBuⁿ)₂, Mo(OBuⁿ)₄, In(OBu^{t})₃, Ga(OBu^{t})₃, Zn(OBu^{t})₂, Al(OBu^{t})₃, Ge(OBu^{t})₄, Sn(OBu^{t})₂, Mo(OBu^{t})₄, and combinations thereof.

In some embodiments, the at least one semiconductor oxide precursor may be selected from the group consisting of In(Cp)₃, Ga(Cp)₃, Zn(Cp)₂, Al(Cp)₃, Ge(Cp)₄, Sn(Cp)₂, Mo(Cp)₄, InMe(Cp)₂, GaMe(Cp)₂, ZnMeCp, AlMe(Cp)₂, GeMe(Cp)₃, SnMeCp, MoMe(Cp)₃, and combinations thereof.

In some embodiments, the at least one semiconductor oxide precursor may be selected from the group consisting of tri(dimethylamino)indium (In[N(Me)₂]₃), tri(diethylamino) indium (In[N(Et)₂]₃), tri(di-n-propylamino)indium (In[N(Prⁿ)₂]₃), tri(di-iso-propylamino)indium (In[N(Prⁱ)₂]₃), tri(di-n-butylamino)indium (In[N(Buⁿ)₂]₃), tri(di-tert-butylamino)indium (In[N(Bu^{t})₂]₃), and combinations thereof.

In some embodiments, the at least one semiconductor oxide precursor may be selected from the group consisting of tri(dimethylamino)gallium (Ga[N(Me)₂]₃), tri(diethylamino)gallium (Ga[N(Et)₂]₃), tri(di-n-propylamino)gallium (Ga[N(Prⁿ)₂]₃), tri(di-iso-propylamino)gallium (Ga[N(Prⁱ)₂]₃), tri(di-n-butylamino)gallium (Ga[N(Buⁿ)₂]₃), tri(di-tert-butylamino)gallium (Ga[N(Bu^{t})₂]₃), and combinations thereof.

In some embodiments, the at least one semiconductor oxide precursor may be selected from the group consisting of di(dimethylamino)zinc (Zn[N(Me)₂]₂), di(diethylamino)zinc (Zn[N(Et)₂]₂), di(di-n-propylamino)zinc (Zn[N(Prⁿ)₂]₂), di(di-iso-propylamino)zinc (Zn[N(Prⁱ)₂]₂), di(di-n-butylamino)zinc (Zn[N(Buⁿ)₂]₂), di(di-tert-butylamino)zinc (Zn[N(Bu^{t})₂]₂), and combinations thereof.

In some embodiments, the at least one semiconductor oxide precursor may be selected from the group consisting of tri(dimethylamino)aluminum (Al[N(Me)₂]₃), tri(diethylamino)aluminum (Al[N(Et)₂]₃), tri(di-n-propylamino)aluminum (Al[N(Prⁿ)₂]₃), tri(di-iso-propylamino)aluminum (Al[N(Prⁱ)₂]₃), tri(di-n-butylamino)aluminum (Al[N(Buⁿ)₂]₃), tri(di-tert-butylamino)aluminum (Al[N(Bu^{t})₂]₃), and combinations thereof.

In some embodiments, the at least one semiconductor oxide precursor may be selected from the group consisting of tetrakis(dimethylamino)germanium (Ge[N(Me)₂]₄), tetrakis(diethylamino)germanium (Ge[N(Et)₂]₄), tetrakis(di-n-propylamino)germanium (Ge[N(Prⁿ)₂]₄), tetrakis(di-iso-propylamino)germanium (Ge[N(Prⁱ)₂]₄), tetrakis(di-n-butylamino)germanium (Ge[N(Buⁿ)₂]₄), tetrakis(di-tert-butylamino)germanium (Ge[N(Bu^{t})₂]₄), and combinations thereof.

In some embodiments, the at least one semiconductor oxide precursor may be selected from the group consisting of di(dimethylamino)tin (Sn[N(Me)₂]₂), di(diethylamino)tin (Sn[N(Et)₂]₂), di(di-n-propylamino)tin (Sn[N(Prⁿ)₂]₂), di(di-iso-propylamino)tin (Sn[N(Prⁱ)₂]₂), di(di-n-butylamino)tin (Sn[N(Buⁿ)₂]₂), di(di-tert-butylamino)tin (Sn[N(Bu^{t})₂]₂), and combinations thereof.

In some embodiments, the at least one semiconductor oxide precursor may be selected from the group consisting of tetrakis(dimethylamino)molybdenum (Mo[N(Me)₂]₄), tetrakis(diethylamino)molybdenum (Mo[N(Et)₂]₄), tetrakis(di-n-propylamino)molybdenum (Mo[N(Prⁿ)₂]₄), tetrakis(di-iso-propylamino)molybdenum (Mo[N(Prⁱ)₂]₄), tetrakis(di-n-butylamino)molybdenum (Mo[N(Buⁿ)₂]₄), tetrakis(di-tert-butylamino)molybdenum (Mo[N(Bu^{t})₂]₄), and combinations thereof.

Suitable oxygen reactants include H₂O, H₂O₂, O₃, O₂, O-containing plasma, N₂O, NO, N₂O₅, or oxygen radicals. Deposition of the semiconductor oxide may, in some embodiments, include alternately and sequentially exposing the substrate to the at least one precursor compound and one or more oxygen reactant(s), for instance, by means of cyclical deposition process (e.g., atomic layer deposition (ALD)) as described in greater detail below.

In particular embodiments, the semiconductor oxide film may consist of InGaZnO (IGZO), wherein the IGZO has a stoichiometry ratio of elements (In:Ga:Zn) of about 0.1:1:1 to 10:1:1, or 1:0.1:1 to 1:10:1, or 1:1:0.1 To 1:1:10, or 0.1:0.1:1 to 10:10:1, or 0.1:1:0.1 to 10:1:10, or 1:0.1:0.1 to 1:10:10, or 1:1:1. In some embodiments, the semiconductor oxide film may consist of InGaZnO (IGZO), wherein the IGZO has a stoichiometry ratio of elements (In:Ga:Zn) of about 0.01:1:1 to 100:1:1, or 1:0.01:1 to 1:100:1, or 1:1:0.01 to 1:1:100, or 0.01:0.01:1 to 100:100:1, or 0.01:1:0.01 to 100:1:100, or 1:0.01:0.01 to 1:100:100.

In some embodiments, the semiconductor oxide film has less than 20 atomic %, less than 10 atomic %, less than 5 atomic %, less than 2 atomic %, less than 1 atomic %, or less than 0.5 atomic % of carbon impurities. In some embodiments, the semiconductor oxide film has less than 30 atomic %, less than 20 atomic %, less than 10 atomic %, less than 5 atomic %, less than 3 atomic %, or less than 1 atomic % of hydrogen impurities.

In particular embodiments, the semiconductor oxide film may comprise one or more dopant element(s) selected from the group consisting of Ce, Pr, Nd, Pm, Sm, E u, Gd, Tb, Dy, Ho, Er, Tm, Y, Lu, Yb, Li, Na, K, and mixtures thereof. The addition of dopant element(s) may advantageously provide that the electrical properties of the semiconductor oxide film may be steered to tailor, for instance, the carrier concentration and mobility within the film. This has the advantage that, when serving as the channel region of a FET, the threshold voltage (i.e., gate voltage at which the transistor begins to conduct electrical charges) can be engineered to meet the desired operating conditions, enabling improved transistor switching between an ON and OFF state.

Hence, the present disclosure provides high flexibility in the design of the semiconductor oxide film through controlled deposition. In some embodiments, the semiconductor oxide film may be formed or deposited prior to the formation or deposition of the metal oxide film and metal film liner as described herein. In other words, the metal oxide film and metal film liner structure may overly at least a portion of the semiconductor oxide film positioned on the substrate.

Accordingly, and in an exemplary embodiment, the method for forming the electrode contact layer comprising a metal oxide film and a metal film liner of the present disclosure may comprise the steps of: a) providing a substrate into a reaction chamber, wherein the substrate comprises a semiconductor oxide film on at least a portion of a surface of the substrate; b) executing one or more cycles, each cycle comprising: i. a first metal precursor pulse, wherein at least a part of the semiconductor oxide film is contacted with one or more first metal precursor(s), by introducing the first metal precursor(s) into the reaction chamber; ii. an oxygen reactant pulse, wherein at least a part of the semiconductor oxide film is contacted with one or more oxygen reactant(s), by introducing the oxygen reactant(s) into the reaction chamber; thereby forming the metal oxide film on the semiconductor oxide film; and, c) executing one or more further cycles, each further cycle comprising: a second metal precursor pulse, wherein at least a part of the metal oxide film is contacted with one or more second metal precursor(s), by introducing the second metal precursor(s) into the reaction chamber; thereby forming the metal film on the metal oxide film.

In some embodiments, the semiconductor oxide film may be formed or deposited after the formation or deposition of the electrode contact layer comprising a metal oxide film and a metal film liner as described herein. In this case, a sacrificial film covers at least a portion of the substrate, which may be replaced with the semiconductor oxide film after deposition of the metal oxide film and metal film liner structure. Replacing the sacrificial film with the semiconductor oxide film may comprise removing at least a part of the sacrificial film after deposition of a desired structure, and filling at least a part of the space from which the sacrificial film is removed with the semiconductor oxide film. This has the advantage that a desired pattern or structure can be formed more selectively.

Accordingly, and in an exemplary embodiment, the method for forming the electrode contact layer comprising a metal oxide film and a metal film liner of the present disclosure may comprise the steps of: a) providing a substrate into a reaction chamber, wherein the substrate comprises a sacrificial film on at least a portion of a surface of the substrate; b) executing one or more cycles, each cycle comprising: i. a first metal precursor pulse, wherein at least a part of the sacrificial film is contacted with one or more first metal precursor(s), by introducing the first metal precursor(s) into the reaction chamber; ii. an oxygen reactant pulse, wherein at least a part of the sacrificial film is contacted with one or more oxygen reactant(s), by introducing the oxygen reactant(s) into the reaction chamber; thereby forming the metal oxide film on the sacrificial film; c) executing one or more further cycles, each further cycle comprising: a second metal precursor pulse, wherein at least a part of the metal oxide film is contacted with one or more second metal precursor(s), by introducing the second metal precursor(s) into the reaction chamber; thereby forming the metal film on the metal oxide film; and, d) removing at least a part of the sacrificial film, thereby forming a free space or cavity, and forming a semiconductor oxide film in the free space or cavity.

In particular embodiments, the step of removing at least a part of the sacrificial film comprises etching the sacrificial film. Preferably, the step of etching the sacrificial film comprises contacting at least part of the sacrificial film with an etchant.

In particular embodiments, the substrate may further comprise an insulating or (high-k) dielectric material layer arranged between the semiconductor oxide film or sacrificial film and the formed metal oxide film and metal film liner structure.

In some embodiments, the high-k material comprises an oxide selected from the group consisting of Al₂O₃, HfZrO₂, HfO₂, ZrO₂, TiO₂, HfSiO₄, and Ta₂O₅. In some embodiments, the oxide may be deposited (e.g., using a cyclical deposition process as described herein below) using at least one metal precursor, such as an aluminum precursor, hafnium precursor, zirconium precursor, titanium precursor, or tantalum precursor; and one or more oxygen reactant(s).

The metal precursor may further comprise any suitable ligand that enables fast evaporation of the metal precursor.

For instance, the at least one metal precursor may further comprise one or more halogen selected from the group consisting of fluoro (F), chloro (Cl), bromo (Br), iodo (I), and combinations thereof.

For instance, the at least one metal precursor may further comprise one or more alkyl as defined herein.

For instance, the at least one metal precursor may further comprise one or more alkoxy as defined herein, preferably a C₁₋₄alkoxy.

For instance, the at least one metal precursor may further comprise one or more cyclopentadienyl.

For instance, the at least one metal precursor may further comprise one or more dialkylamine (—NR^{a}R^{b}), wherein R^{a} and R^{b} are an alkyl as defined herein, preferably a C₁₋₄alkyl as defined herein.

It should be understood that within the scope of the present disclosure the metal precursor may comprise any combination of the aforementioned types of ligands.

In some embodiments, the at least one metal precursor may be selected from the group consisting of HfCl₄, ZrCl₄, AlCl₃, TaCl₅, TiCl₄, SiCl₄, HfBr₄, ZrBr₄, AlBr₃, TaBrs, TiBr₄, SiBr₄, Hfl₄, ZrI₄, AlI₃, TaI₅, TiI₄, SiI₄, and combinations thereof.

In some embodiments, the at least one metal precursor may be selected from the group consisting of HfMe₄, ZrMe₄, AlMe₃, TaMe₅, TiMe₄, SiMe₄, HfEt₄, ZrEt₄, AlEt₃, TaEt₅, TiEt₄, SiEt₄, HfEt₄, ZrEt₄, AlEt₃, TaEt₅, TiEt₄, SiEt₄, Hf(Prⁿ)₄, Zr(Prⁿ)₄, Al(Prⁿ)₃, Ta(Prⁿ)s, Ti(Prⁿ)₄, Si(Prⁿ)₄, Hf(Prⁱ)₄, Zr(Prⁱ)₄, Al(Prⁱ)₃, Ta(Prⁱ)s, Ti(Prⁱ)₄, Si(Prⁱ)₄, Hf(Buⁿ)₄, Zr(Buⁿ)₄, Al(Buⁿ)₃, Ta(Buⁿ)s, Ti(Buⁿ)₄, Si(Buⁿ)₄, Hf(Bu^{t})₄, Zr(Bu^{t})₄, Al(Bu^{t})₃, Ta(Bu^{t})₅, Ti(Bu^{t})₄, Si(Bu^{t})₄, and combinations thereof.

In some embodiments, the at least one metal precursor may be selected from the group consisting of Hf(OMe)₄, Zr(OMe)₄, Al(OMe)₃, Ta(OMe)s, Ti(OMe)₄, Si(OMe)₄, Hf(OEt)₄, Zr(OEt)₄, Al(OEt)₃, Ta(OEt)s, Ti(OEt)₄, Si(OEt)₄, Hf(OEt)₄, Zr(OEt)₄, Al(OEt)₃, Ta(OEt)s, Ti(OEt)₄, Si(OEt)₄, Hf(OPrⁿ)₄, Zr(OPrⁿ)₄, Al(OPrⁿ)₃, Ta(OPrⁿ)s, Ti(OPrⁿ)₄, Si(OPrⁿ)₄, Hf(OPrⁱ)₄, Zr(OPrⁱ)₄, Al(OPrⁱ)₃, Ta(OPrⁱ)s, Ti(OPrⁱ)₄, Si(OPrⁱ)₄, Hf(OBuⁿ)₄, Zr(OBuⁿ)₄, Al(OBuⁿ)₃, Ta(OBuⁿ)s, Ti(OBuⁿ)₄, Si(OBuⁿ)₄, Hf(OBu^{t})₄, Zr(OBu^{t})₄, Al(OBu^{t})₃, Ta(OBu^{t})₅, Ti(OBu^{t})₄, Si(OBu^{t})₄, and combinations thereof.

In some embodiments, the at least one metal precursor may be selected from the group consisting of Hf(Cp)₄, Zr(Cp)₄, Al(Cp)₃, Ta(Cp)s, Ti(Cp)₄, Si(Cp)₄, HfMe(Cp)₃, ZrMe(Cp)₃, AlMe(Cp)₂, TaMe(Cp)₄, TiMe(Cp)₃, SiMe(Cp)₃, and combinations thereof.

In some embodiments, the at least one metal precursor may be selected from the group consisting of tetrakis(dimethylamino)hafnium (Hf[N(Me)₂]₄), tetrakis(diethylamino)hafnium (Hf[N(Et)₂]₄), tetrakis(di-n-propylamino)hafnium (Hf[N(Prⁿ)₂]₄), tetrakis(di-iso-propylamino)hafnium (Hf[N(Prⁱ)₂]₄), tetrakis(di-n-butylamino)hafnium (Hf[N(Buⁿ)₂]₄), tetrakis(di-tert-butylamino)hafnium (Hf[N(Bu^{t})₂]₄), and combinations thereof.

In some embodiments, the at least one metal precursor may be selected from the group consisting of tetrakis(dimethylamino)zirconium (Zr[N(Me)₂]₄), tetrakis(diethylamino)zirconium (Zr[N(Et)₂]₄), tetrakis(di-n-propylamino)zirconium (Zr[N(Prⁿ)₂]₄), tetrakis(di-iso-propylamino)zirconium (Zr[N(Prⁱ)₂]₄), tetrakis(di-n-butylamino)zirconium (Zr[N(Buⁿ)₂]₄), tetrakis(di-tert-butylamino)zirconium (Zr[N(Bu^{t})₂]₄), and combinations thereof.

In some embodiments, the at least one metal precursor may be selected from the group consisting of tri(dimethylamino)aluminium (Al[N(Me)₂]₃), tri(diethylamino)aluminium (Al[N(Et)₂]₃), tri(di-n-propylamino)aluminium (Al[N(Prⁿ)₂]₃), tri(di-iso-propylamino)aluminium (Al[N(Prⁱ)₂]₃), tri(di-n-butylamino)aluminium (Al[N(Buⁿ)₂]₃), tri(di-tert-butylamino)aluminium (Al[N(Bu^{t})₂]₃), and combinations thereof.

In some embodiments, the at least one metal precursor may be selected from the group consisting of penta(dimethylamino)tantalum (Ta[N(Me)₂]₅), penta(diethylamino)tantalum (Ta[N(Et)₂]₅), penta(di-n-propylamino)tantalum (Ta[N(Prⁿ)₂]₅), penta(di-iso-propylamino)tantalum (Ta[N(Prⁱ)₂]₅), penta(di-n-butylamino)tantalum (Ta[N(Buⁿ)₂]₅), penta(di-tert-butylamino)tantalum (Ta[N(Bu^{t})₂]₅), and combinations thereof.

In some embodiments, the at least one metal precursor may be selected from the group consisting of tetrakis(dimethylamino)titanium (Ti[N(Me)₂]₄), tetrakis(diethylamino)titanium (Ti[N(Et)₂]₄), tetrakis(di-n-propylamino)titanium (Ti[N(Prⁿ)₂]₄), tetrakis(di-iso-propylamino)titanium (Ti[N(Prⁱ)₂]₄), tetrakis(di-n-butylamino)titanium (Ti[N(Buⁿ)₂]₄), tetrakis(di-tert-butylamino)titanium (Ti[N(Bu^{t})₂]₄), and combinations thereof.

In some embodiments, the at least one metal precursor may be selected from the group consisting of tetrakis(dimethylamino)silicon (Si[N(Me)₂]₄), tetrakis(diethylamino)silicon (Si[N(Et)₂]₄), tetrakis(di-n-propylamino)silicon (Si[N(Prⁿ)₂]₄), tetrakis(di-iso-propylamino)silicon (Si[N(Prⁱ)₂]₄), tetrakis(di-n-butylamino)silicon (Si[N(Buⁿ)₂]₄), tetrakis(di-tert-butylamino)silicon (Si[N(Bu^{t})₂]₄), and combinations thereof.

Suitable oxygen reactants include H₂O, H₂O₂, O₃, O₂, O-containing plasma, N₂O, NO, N₂O₅, or oxygen radicals.

In accordance with step b) of the present method, and after providing the substrate to the reaction chamber, one or more (deposition) cycles are executed to form the metal oxide film on the semiconductor oxide film or the sacrificial film. Subsequently, and in accordance with step c) of the present method, one or more (different deposition) cycles are executed to form the metal film on the (previously deposited) metal oxide film.

In particular, the present (deposition) method may be a cyclical deposition process, preferably a combination of cyclical deposition processes, such as an atomic layer deposition (ALD) process or a cyclical chemical vapor deposition (CVD) process. Each cyclical deposition process comprises one or more distinct (deposition) cycles. In particular embodiments, the method as disclosed herein may be an ALD method. In contrast to sputtering techniques commonly used within the state of the art for deposition of thin films and layers for the manufacturing of various semiconductors and transistors, cyclical deposition processes such as ALD were found to provide more uniform deposition across the surface of the substrate and/or (previously) deposited layers.

As used herein, the synonymous terms “deposition” or “cyclic deposition” or “cyclic deposition process” or “cyclical deposition process” refer to a sequential introduction of precursors (and/or reactants) into a reaction chamber to deposit a layer or film over a substrate and includes processing techniques such as ALD, CVD, and hybrid cyclical deposition processes that include an ALD component and a CVD component. Typically, one deposition cycle may form a film or layer of about 0.10 nm. However, the experimental thickness may vary depending on the amount and type of cycles and available reaction sites on the substrate and/or a previously deposited layer.

The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

In ALD processes, during each cycle, generally a precursor (e.g. a first metal precursor or a second metal precursor) is introduced to a reaction chamber and is chemisorbed to a deposition surface (e.g., a substrate surface that can include a previously deposited material from a previous ALD cycle or other material), thereby forming a material, e.g. about a monolayer or sub-monolayer of material, or several monolayers of material, or a plurality of monolayers of material, which does not readily react with additional precursor (i.e., a self-limiting reaction). Thereafter, in some cases, a reactant (e.g., another precursor or reaction gas such as an oxygen reactant) may be introduced into the process chamber. The reactant can be capable of further reaction with the precursor. It should be noted that, as used herein, ALD processes are not necessarily comprised of a sequence of self-limiting surface reactions.

Optionally, purging steps can be utilized during one or more repetitions, e.g. during each deposition step, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gases that react with each other. For example, a purge, e.g. using an inert gas such as a noble gas, may be provided between subsequent pulses, thus avoiding or at least minimizing gas phase interactions between precursor(s) and/or reactant(s).

In particular embodiments, the method as disclosed herein provides that the reaction chamber is purged before and/or after each precursor pulse. In particular embodiments, the method as disclosed herein provides that the reaction chamber is purged before and/or after each first metal precursor pulse and oxygen reactant pulse or each second metal precursor pulse.

Advantageously, a cyclical deposition process as disclosed herein can be a thermal deposition process. In other words, in some embodiments, none of the pulses or purges in the cyclical deposition process employs a plasma. In the case of thermal cyclical deposition processes, a duration of the step of providing the first metal precursor to the reaction chamber, a duration of the step of providing the second metal precursor to the reaction chamber, and/or a duration of the step of providing the oxygen reactant to the reaction chamber can be relatively long to allow the precursors and/or reactants to react with a surface of the substrate and/or a previously deposited layer. For example, the duration can be greater than or equal to 5 seconds or greater than or equal to 10 seconds or between about 5 and 10 seconds.

In some embodiments, the cyclical deposition process employs a plasma-enhanced deposition technology. For example, the cyclical deposition process may comprise a plasma-enhanced atomic layer deposition process and/or a plasma-enhanced chemical vapor deposition process. In such a case, any one of the pulses in the cyclical depositing process may comprise generating a plasma in the reaction chamber.

In some embodiments, the method as disclosed herein may be a continuous vacuum deposition process. In the context of a continuous vacuum deposition process, a material is deposited onto a substrate in a reaction chamber without the introduction of atmospheric air or any interruptions that would break the controlled vacuum environment. This process involves maintaining a consistent vacuum pressure within the reaction chamber.

In particular embodiments, the method as disclosed herein provides that the metal oxide film may be formed without any intervening vacuum break. The term “without any intervening vacuum break” can refer to without breaking a vacuum, without interruption as a timeline, without any material intervening step, without changing treatment conditions, and/or immediately thereafter.

In particular embodiments, the method as disclosed herein provides that the metal film may be formed without any intervening vacuum break.

In particular embodiments, the method as disclosed herein provides that the electrode contact layer comprising a metal oxide film and metal film liner may be formed without any intervening vacuum break.

In particular embodiments, the method as disclosed herein provides that the semiconducting oxide film, the electrode contact layer comprising a metal oxide film and metal film liner, and optionally the sacrificial film may be formed without any intervening vacuum break. This has the advantage that the present disclosure avoids the need for repeated evacuations and purges of the reaction chamber that are common in traditional batch deposition methods.

In particular embodiments, the formation of the metal oxide film may comprise at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 1000 cycles, or from at least 2 cycles to at most 100 cycles, or from at least 5 cycles to at most 50 cycles.

In particular embodiments, the formation of the metal film may comprise at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 1000 cycles, or from at least 2 cycles to at most 100 cycles, or from at least 5 cycles to at most 50 cycles.

Each cycle may comprise one or more pulses. In some embodiments, at least one pulse involves a self-limiting surface reaction. In some embodiments, all pulses involve a self-limiting surface reaction. In the context of ALD, a self-limiting surface reaction refers to a chemical reaction that automatically halts or slows down once a certain threshold or coverage is reached on a surface, for instance, once a complete monolayer or sub-monolayer is formed the reactions stops by preventing further reaction with additional precursor. In some embodiments, a cycle comprises one or more precursor pulse(s), optionally one or more dopant pulse(s), and/or one or more reactant pulse(s).

In particular embodiments, the metal oxide film may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm. In particular embodiments, the method as disclosed herein provides that the channel layer may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm.

In particular embodiments, the metal film may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm. In particular embodiments, the method as disclosed herein provides that the channel layer may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm.

In particular embodiments, the semiconductor oxide film may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm. In particular embodiments, the method as disclosed herein provides that the channel layer may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm.

In some embodiments, the metal oxide film and/or the metal film may have a growth rate of 0.10 nm or less per cycle of precursor(s)/reactive gas(es), and purge (e.g., inert carrier) gas(es). A layer of lower thickness may be desirable for many electronics applications, including transistors.

The method as disclosed herein relies on the execution of one or more cycles to grow at least one thin-film metal oxide layer and one or more cycles to grow at least one thin-film metal layer. In some embodiments, at least one pulse involves a self-limiting surface reaction. In some embodiments, all pulses involve a self-limiting surface reaction.

In some embodiments, a cycle to grow a metal oxide film may comprise the following sequence of pulses: a first metal precursor pulse, and an oxygen reactant pulse. In the first metal precursor pulse one or more first metal precursor(s) is provided into the reaction chamber and may chemisorb to the substrate (i.e., adheres and forms chemical bonds with atoms or molecules on the surface of said substrate and/or a previously deposited layer or material). In the oxygen reactant pulse, one or more oxygen reactant(s) is provided into the reaction chamber and may react with the chemisorbed first metal to form a metal oxide film or layer on at least a part of the substrate. The number of cycles determines the overall thickness of the deposited metal oxide film.

In some embodiments, a cycle to grow a metal film may comprise the following sequence of pulses: a second metal precursor pulse. In the second metal precursor pulse one or more second metal precursor(s) is provided into the reaction chamber and may chemisorb to the deposited metal oxide film (i.e., adheres and/or forms chemical bonds with atoms or molecules on the surface of said metal oxide film). The number of cycles determines the overall thickness of the deposited metal film.

An advantage of the presently disclosed cyclical deposition process(es) is the precise control over the overall layer thickness (and dopant incorporation as described herein below).

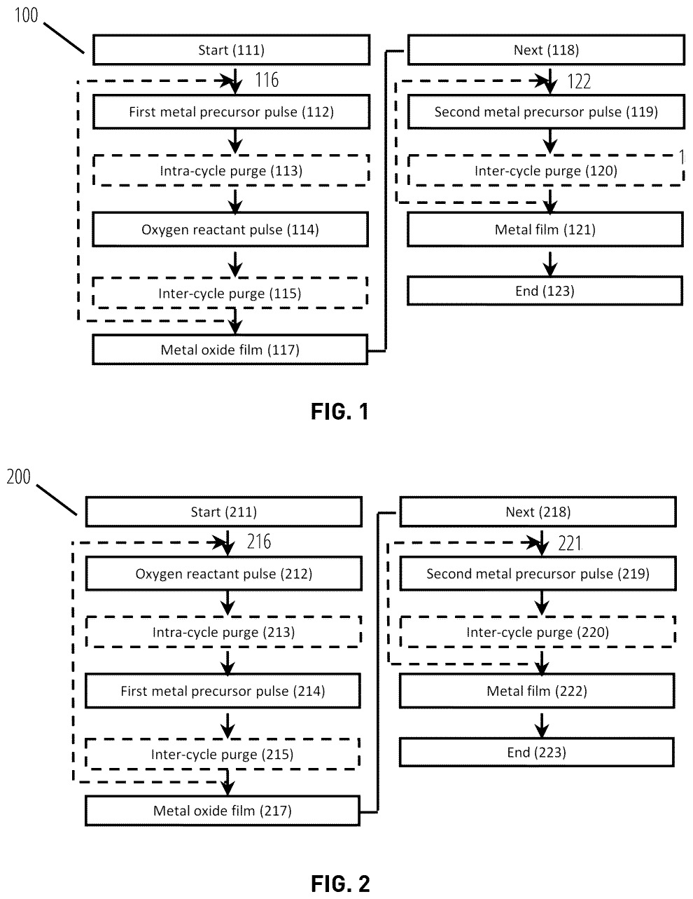

FIG. 1. describes an exemplary embodiment of the method (100) as described herein for the manufacturing of an electrode contact layer, suitable for the production of a FET, as disclosed herein. The method starts (111) after a substrate has been provided to a reaction chamber. The cyclical deposition process comprises providing one or more first metal precursor (gas) into the reaction chamber in a first metal precursor pulse (112). Optionally, the reaction chamber is purged (113) after the first metal precursor pulse (112). Then, one or more oxygen reactant is provided to the reaction chamber in an oxygen reactant pulse (114). Optionally, the reaction chamber can be purged (115) after the oxygen reactant pulse.

The first metal precursor pulse (112), the oxygen reactant pulse (114), and the optional purges (113,115) can be repeated (116) any number of times to obtain a metal oxide film (117) having a desired thickness. When a metal oxide film having a desired thickness has been deposited, the method continues (118) to deposit the metal film.

One or more second metal precursor (gas) is provided to the reaction chamber in a second metal precursor pulse (119). Optionally, the reaction chamber is purged (120) after the second metal precursor pulse (119). The second metal precursor pulse (119), and the optional purge (120) can be repeated (121) any number of times to obtain a desired thickness of a metal film (122).

The method concludes (123) when the desired liner combination is formed based on any combination of the aforementioned steps. Once the method has ended, the substrate can be subjected to additional processes known in the art for forming a device structure and/or device (e.g., a FET).

It should be appreciated that the first metal precursor pulse (112) and the oxygen reactant pulse (114) may overlap in a cycle. Further, the sequence of each method step (112 to 115) within each cycle may vary. For instance, and in another exemplary embodiment, a cycle may comprise the consecutive steps of an oxygen reactant pulse and a first metal precursor pulse. Hence, an oxygen reactant pulse may precede a first metal precursor pulse.

FIG. 2. describes an exemplary embodiment of the method (200) as described herein for the manufacturing of an electrode contact layer, suitable for the production of a FET, as disclosed herein. The method starts (211) after a substrate has been provided to a reaction chamber. The cyclical deposition process comprises providing one or more oxygen reactant(s) into the reaction chamber in an oxygen reactant pulse (212). Optionally, the reaction chamber can be purged (213) after the oxygen reactant pulse (212). Then, one or more first metal precursor(s) (gas) is provided to the reaction chamber in a first metal precursor pulse (214). Optionally, the reaction chamber is purged (215) after the first metal precursor pulse.

The oxygen reactant pulse (212), the first metal precursor pulse (214), and the optional purges (213,215) can be repeated (216) any number of times to obtain a metal oxide film (217) having a desired thickness. When a metal oxide film having a desired thickness has been deposited, the method continues (218) to deposit the metal film.

One or more second metal precursor(s) (gas) is provided to the reaction chamber in a second metal precursor pulse (219). Optionally, the reaction chamber is purged (220) after the second metal precursor pulse (219). The second metal precursor pulse (219), and the optional purge (220) can be repeated (221) any number of times to obtain a desired thickness of a metal film (222).

The method concludes (223) when the desired liner combination is formed based on any combination of the aforementioned steps. Once the method has ended, the substrate can be subjected to additional processes known in the art for forming a device structure and/or device (e.g., a FET).

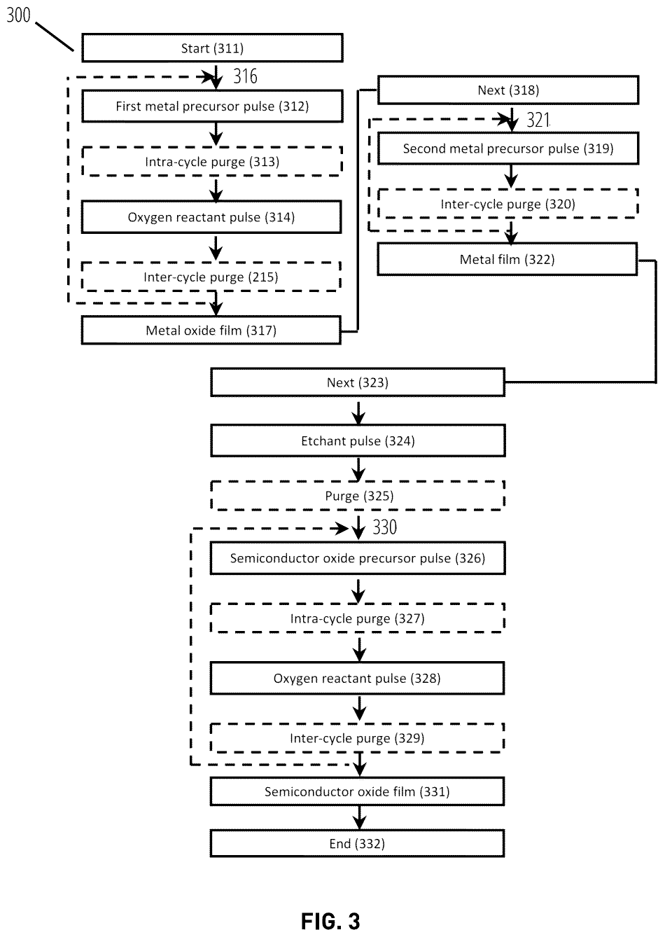

FIG. 3. describes an exemplary embodiment of the method (300) as described herein for the manufacturing of an electrode contact layer, suitable for the production of a FET, as disclosed herein. The method starts (311) after a substrate comprising a sacrificial film has been provided to a reaction chamber. The cyclical deposition process comprises providing one or more first metal precursor(s) (gas) into the reaction chamber in a first metal precursor pulse (312). Optionally, the reaction chamber is purged (313) after the first metal precursor pulse (312). Then, one or more oxygen reactant(s) is provided to the reaction chamber in an oxygen reactant pulse (314). Optionally, the reaction chamber can be purged (315) after the oxygen reactant pulse.

The first metal precursor pulse (312), the oxygen reactant pulse (314), and the optional purges (313,315) can be repeated (316) any number of times to obtain a metal oxide film (317) having a desired thickness. When a metal oxide film having a desired thickness has been deposited, the method continues (318) to deposit the metal film.

One or more second metal precursor(s) (gas) is provided to the reaction chamber in a second metal precursor pulse (319). Optionally, the reaction chamber is purged (320) after the second metal precursor pulse (319). The second metal precursor pulse (319), and the optional purge (320) can be repeated (321) any number of times to obtain a metal film (322) having a desired thickness. When a metal film having a desired thickness has been deposited, the method continues (323) to replace the sacrificial film with a semiconductor oxide film.

One or more etchant (gas) is provided into the reaction chamber in an etchant pulse (324) to remove at least a part of the sacrificial film positioned on the substrate. Optionally, the reaction chamber is purged (325) after the etchant pulse (324). Next, one or more semiconductor oxide precursor(s) (gas) is provided into the reaction chamber in a semiconductor oxide precursor pulse (326). Optionally, the reaction chamber is purged (327) after the semiconductor oxide precursor pulse (326). Then, one or more oxygen reactant(s) is provided to the reaction chamber in an oxygen reactant pulse (328). Optionally, the reaction chamber can be purged (329) after the oxygen reactant pulse.

The etchant pulse (324), semiconductor oxide precursor pulse (326), the oxygen reactant pulse (328), and the optional purges (325,327,329) can be repeated (330) any number of times to obtain a desired thickness of a semiconductor oxide film (331).

The method concludes (332) when the desired structure is formed based on any combination of the aforementioned steps. Once the method has ended, the substrate can be subjected to additional processes known in the art for forming a device structure and/or device (e.g., a FET).

It should be appreciated that the semiconductor oxide precursor pulse (326) and the oxygen reactant pulse (328) may overlap in a cycle. Further, the sequence of each method step (326 to 329) within each cycle may vary. For instance, and in another exemplary embodiment, a cycle may comprise the consecutive steps of an oxygen reactant pulse and a semiconductor oxide precursor pulse. Hence, an oxygen reactant pulse may precede a semiconductor oxide precursor pulse.

In some particular embodiments, a cycle, and optionally each cycle, in step b) of the method as disclosed herein may further comprise:
i. a dopant pulse, wherein at least a part of the semiconductor oxide film or the sacrificial film is contacted with one or more dopant(s), by introducing the dopant in the reaction chamber.

In other words, the metal oxide film deposited in step b) of the present method may be doped with one or more dopant(s) to engineer the electronic properties of the metal oxide film. This has the advantage that the conductivity and functionality of the electrode contact layer comprising a metal oxide film and a metal film liner may be improved.

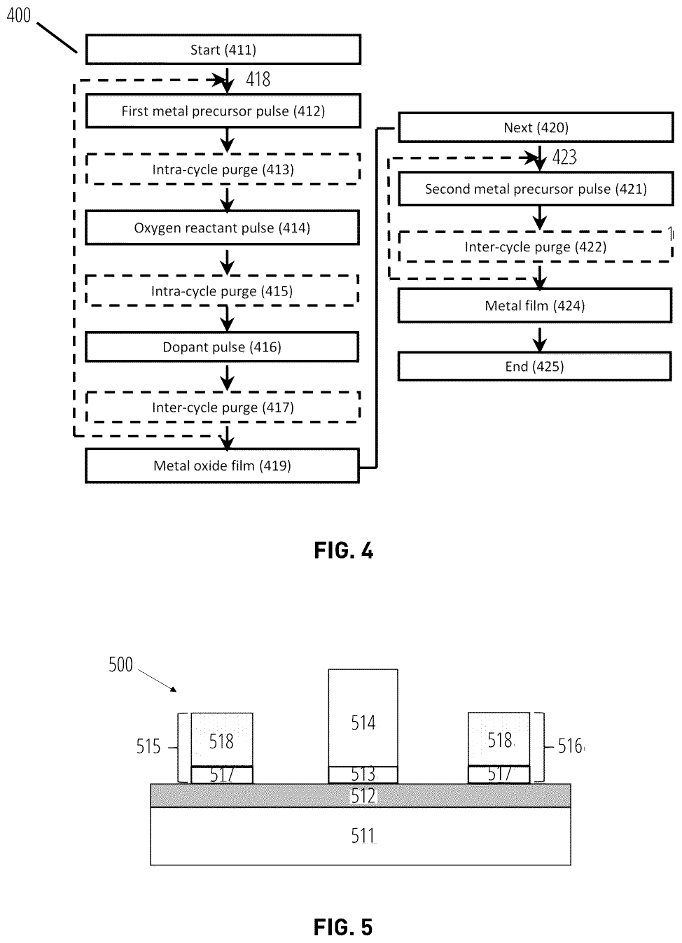

FIG. 4. describes an exemplary embodiment of the method (400) as described herein for the manufacturing of an electrode contact layer, suitable for the production of a FET, as disclosed herein. The method starts (411) after a substrate has been provided to a reaction chamber. The cyclical deposition process comprises providing one or more first metal precursor(s) (gas) into the reaction chamber in a first metal precursor pulse (412). Optionally, the reaction chamber is purged (413) after the first metal precursor pulse (412). Then, one or more oxygen reactant(s) is provided to the reaction chamber in an oxygen reactant pulse (414). Optionally, the reaction chamber can be purged (415) after the oxygen reactant pulse. Then, one or more dopant(s) is provided to the reaction chamber in a dopant pulse (416). Optionally, the reaction chamber can be purged (417) after the dopant pulse.

The first metal precursor pulse (412), the oxygen reactant pulse (414), the dopant pulse (416), and the optional purges (413,415,417) can be repeated (418) any number of times to obtain a doped metal oxide film (419) having a desired thickness. When a metal oxide film having a desired thickness has been deposited, the method continues (420) to deposit the metal film.

One or more second metal precursor(s) (gas) is provided to the reaction chamber in a second metal precursor pulse (421). Optionally, the reaction chamber is purged (422) after the second metal precursor pulse (421). The second metal precursor pulse (421), and the optional purge (422) can be repeated (423) any number of times to obtain a desired thickness of a metal film (424).

The method concludes (425) when the desired liner combination is formed based on any combination of the aforementioned steps. Once the method has ended, the substrate can be subjected to additional processes known in the art for forming a device structure and/or device (e.g., a FET).

It should be appreciated that the first metal precursor pulse (412), the oxygen reactant pulse (414), and the dopant pulse (416) may overlap in a cycle. Further, the sequence of each method step (412 to 417) within each cycle may vary.

For instance, and in another exemplary embodiment, a cycle may comprise the consecutive steps of an oxygen reactant pulse, a dopant pulse, and a first metal precursor pulse. Hence, an oxygen reactant pulse may precede a dopant pulse and a first metal precursor pulse. Alternatively, and another exemplary embodiment, a cycle may comprise the consecutive steps of a dopant pulse, an oxygen reactant pulse, and a first metal precursor pulse. Hence, a dopant pulse may precede an oxygen reactant pulse and a first metal precursor pulse.

In particular embodiments, the method as disclosed herein provides that the first metal precursor pulse, the second metal precursor pulse, the optional dopant pulse, and/or the oxygen reactant pulse, and optionally the semiconductor oxide precursor pulse, comprise a plurality of micro pulses. A “micro pulse” as used herein is a short period during which one or more first metal precursor precursor(s), one or more second metal precursor precursor(s), optionally one or more dopant(s), and/or one or more oxygen reactant(s), and optionally one or more semiconductor oxide precursor(s) gas may be introduced into the reaction chamber. Hence, the method as disclosed herein provides high flexibility in pulse sequence and length, thereby providing a cost-effective and more efficient method compared to conventional thin-film production processes comprised in the art.

In some embodiments, the first metal precursor pulse, second metal precursor pulse, optional dopant pulse, and optional semiconductor oxide precursor pulse may last from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

In some embodiments, the oxygen reactant pulse may last from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

It shall be understood that any two steps and/or pulses and/or micro pulses can be separated by a purge. Thus, in some embodiments, a first metal precursor pulse, a second metal precursor pulse, optionally a dopant pulse, and/or an oxygen reactant pulse, and optionally a semiconductor oxide precursor pulse, may be separated by a purge. In some embodiments, subsequent cycles are separated by a purge.

In particular embodiments, the reaction chamber may be purged before and/or after a first metal precursor pulse, a second metal precursor pulse, and/or an oxygen reactant pulse, and optionally a semiconductor oxide precursor pulse. An advantage of purging the reaction chamber before and/or after each precursor pulse and/or dopant pulse and/or reactant pulse is that any residual precursor, dopant, reactant and/or reaction byproduct is removed, thereby avoiding cross-contamination between pulses and resulting in films or layers with high purity and less detrimental defects.

In some particular embodiments, the steps of forming one or more metal oxide layer, one or more metal layers, and optionally replacing a sacrificial layer with a semiconductor oxide layer may be performed in the same reaction chamber. Alternatively, and in some embodiments, the steps of forming one or more metal oxide layer, one or more metal layer, and optionally replacing a sacrificial layer with a semiconductor oxide layer may be performed consecutively in the same reaction chamber, preferably without any intervening vacuum break.

In some particular embodiments, the steps of forming one or more metal oxide layer, one or more metal layer, and optionally replacing a sacrificial layer with a semiconductor oxide layer may be performed in separate reaction chambers.

In accordance with step b) of the present method, a metal oxide film is formed on the substrate comprising a semiconductor oxide film or a sacrificial film. As described above, the metal oxide film is deposited by means of one or more deposition cycles comprising a first metal precursor pulse, an oxygen reactant pulse, and optionally a dopant pulse. It has been found that said metal oxide film may avoid oxygen scavenging or interaction of oxygen with components of the semiconductor device, which has a number of advantages.

For instance, the metal oxide film may avoid changes in the oxygen content of the channel layer or the contact layer of a FET, which may stabilize the threshold voltage and contact resistance of the FET, which improves the overall performance and energy efficiency.

Another advantage is that the use of a metal oxide film in the electrode contact layer as described herein may provide for the manufacturing of more reliable semiconductor devices.

In particular embodiments, the one or more first metal precursor(s) comprises an element selected from the group consisting of Mg, In, V, Ti, Cr, Mn, Fe, Co, Ni, Cu, Zn, Zr, Nb, Tc, Ru, Rh, Pd, Ag, Cd, Hf, Ta, W, Re, Os, Ir, Pt, Au, As, Sb, Mo, and Bi.

In accordance with various embodiments of the disclosure, suitable first metal precursors (that permit the deposition of a film or material comprising one or more element(s) listed above) may comprise cyclopentadienyl metal precursors, halide metal precursors, alkyl amide metal precursors, alkoxide metal precursors, and mixtures thereof. In some cases, the first metal precursor comprises a metal atom (e.g., Mg, In, V, Ti, Cr, Mn, Fe, Co, Ni, Cu, Zn, Zr, Nb, Tc, Ru, Rh, Pd, Ag, Cd, Hf, Ta, W, Re, Os, Ir, Pt, Au, As, Sb, Mo, and Bi) directly bonded to one or more nitrogen atom(s) and/or one or more oxygen atom(s) and/or one or more halogen atom(s). In some cases, the first metal precursor can be or include a metal organic precursor as disclosed herein (e.g., cyclopentadienyl metal precursors).

In particular embodiments, the one or more oxygen reactant(s) is selected from the group consisting of H₂O, H₂O₂, O₃, O₂, O-containing plasma, N₂O, NO, N₂O₅, and oxygen radicals.

In particular embodiments, the one or more dopant(s) comprises an element selected from the group consisting of La, Pr, Nd, Pm, Sm, Eu, Gd, Tb, Dy, Ho, Er, Tm, Yb, Lu, Y, Li, Na, K, Rb, Cs, Be, Mg, Ca, Sr, Ba, Al, Ge, Sb, Te, Si, and mixtures thereof.

In particular embodiments, the metal oxide film comprises a metal oxide selected from the group consisting of MgO, In₂O₃, ZnO, ZnMgO, InSnO, InZnO, InMoO, V₂O₅, TiO₂, CrO₂, MnO, FeO, Fe₂O₃, CoO, NiO, Cu₂O, CuO, ZnO, ZrO₂, NbO, NbO₂, TcO₂, RuO₂, Rh₂O₃, Ag₂O, CdO, HfO₂, HfZrO, Ta₂O₅, W₂O₃, ReO₃, OsO₄, IrO₂, PtO₂, Au₂O₃, As₂O₃, Sb₂O₃, Bi₂O₃, and mixtures thereof.

It has been found that the listed metal oxides may advantageously provide a liner combination that may serve as a contact layer of a FET with an improved contact resistance, without losing the ability to conduct and function as a conventional metal contact. In addition, it has been found that the resulting metal oxide film is particularly less prone to oxygen scavenging, when compared to conventional metal contacts.

In accordance with step c) of the present method, a metal film is formed on (at least a part of) the deposited metal oxide film. As described above, the metal film is deposited by means of one or more deposition cycle(s) comprising a second metal precursor pulse. It has been found that said metal oxide film and metal film liner combination may serve as a contact layer of a FET that may provide an optimized balance between conductivity and contact resistance.

In particular embodiments, the metal film comprises metal(s) or metalloid(s) with a work function of at least 4.0 eV, such as between 4.0 eV and 7.0 eV, or between 4.0 eV and 6.5 eV, or between 4.0 eV and 6.0 eV, or between 4.0 eV and 5.5 eV, or between 4.0 eV and 5.0 eV. The “work function” of a metal or metalloid as used herein refers to the amount of energy required to remove an electron from the surface of a solid to a point in vacuum immediately outside the solid surface.

It has advantageously been found that metal or metalloids with a work function of at least 4.0 eV may significantly reduce oxygen scavenging of the liner combination as described herein. Hence, being capable of providing a more stable contact layer, which may result in a more performant FET.

In particular embodiments, the one or more second metal precursor(s) comprises an element selected from the group consisting of Mg, In, V, Ti, Cr, Mn, Fe, Co, Ni, Cu, Zn, Zr, Nb, Tc, Ru, Rh, Pd, Ag, Cd, Hf, Ta, W, Re, Os, Ir, Pt, Au, As, Sb, Mo, and Bi.

In accordance with various embodiments of the disclosure, suitable second metal precursors (that permit the deposition of a film or material comprising one or more element(s) listed above) may comprise cyclopentadienyl metal precursors, halide metal precursors, alkyl amide metal precursors, alkoxide metal precursors, and mixtures thereof. In some cases, the second metal precursor comprises a metal atom (e.g., Mg, In, V, Ti, Cr, Mn, Fe, Co, Ni, Cu, Zn, Zr, Nb, Tc, Ru, Rh, Pd, Ag, Cd, Hf, Ta, W, Re, Os, Ir, Pt, Au, As, Sb, Mo, and Bi) directly bonded to one or more nitrogen atom(s) and/or one or more oxygen atom(s) and/or one or more halogen atom(s). In some cases, the second metal precursor can be or include a metal organic precursor as disclosed herein above (e.g., cyclopentadienyl metal precursors).

The method as disclosed herein may be performed at different temperatures and/or pressures. In particular embodiments, the method as disclosed herein provides that the substrate may be heated to a temperature of about 80° C. to about 400° C., or about 100° C. to about 400° C., or about 125° C. to about 400° C., preferably about 150° C. to about 400° C., or about 175° C. to about 400° C., preferably about 200° C. to about 400° C., or about 250° C. to about 400° C., or about 300° C. to about 400° C. Ise, the substrate is heated in the reaction chamber to a temperature between 80° C. and 400° C. The listed temperatures can decrease the time needed for material deposition, although lower or higher temperatures can be considered still.

In particular embodiments, the method as disclosed herein provides that the pressure in the reaction chamber is between about 0.1 Torr and about 100.0 Torr, or between about 0.5 Torr and about 100.0 Torr, or between about 1.0 Torr and about 100.0 Torr, or between about 2.0 Torr and about 100.0 Torr, or between about 5.0 Torr and about 100.0 Torr, or between about 5.0 Torr and about 80.0 Torr, or preferably between about 5.0 Torr and about 50.0 Torr, or between about 10.0 Torr and about 50.0 Torr. The listed pressures can decrease the time needed for material deposition, although lower or higher pressures can be considered still.

The electrode contact layer comprising a metal oxide film and a metal film liner may be formed in any suitable reactor. Thus, in some embodiments, the liner combination is deposited in a cross-flow reactor. In some embodiments, the liner combination is deposited in a showerhead reactor. In some embodiments, the liner combination is deposited in a hot-wall reactor. In some embodiments, the liner combination is deposited in a cold-wall reactor. Doing so can advantageously enhance uniformity and/or repeatability of the liner combination deposition processes.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the one or more first metal precursor(s), the one or more second metal precursor(s), the one or more oxygen reactant(s), the optional one or more dopant(s), and optional one or more semiconductor oxide precursor(s) is provided to the reaction chamber by means of a carrier gas. Exemplary carrier gases include nitrogen (N₂) and a noble gas such as He, Ne, Ar, Xe, or Kr.

A continuous substrate may extend beyond the bounds of a process/reaction chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet or a flexible material. Continuous substrates may also comprise carriers or sheets upon which non-continuous substrates are mounted.

Another aspect of the present disclosure relates to an electrode contact layer comprising a metal oxide film and a metal film liner obtained or obtainable by the method as disclosed herein.

Another aspect of the present disclosure relates to a semiconductor device. The semiconductor device preferably comprises a substrate and at least one electrode contact layer comprising a metal oxide film and a metal film liner; wherein the metal oxide film is arranged between the substrate and the metal film.

As mentioned before, the electrode contact layer comprising a metal oxide film and a metal film liner may be produced during the manufacturing of a semiconductor device, preferably a semiconductor device as disclosed herein. It is understood that any of the above embodiments relating to the method for producing the electrode contact layer comprising a metal oxide film and a metal film liner, form embodiments for the semiconductor device, and vice versa.

In particular embodiments, the semiconductor device comprises a field effect transistor incorporated into a processing device.

In particular embodiments, the semiconductor device comprises a field effect transistor incorporated into a memory device. In particular embodiments, the semiconductor device disclosed herein provides that the substrate comprises a channel layer comprising one or more semiconductor oxides, and wherein the metal oxide film is arranged between the channel layer and the metal film.

In particular embodiments, the semiconductor device disclosed herein provides that the metal oxide film is in direct or electrical contact with the substrate and the metal film.

Another aspect of the present disclosure relates to a field-effect transistor (FET). The FET preferably comprises: a substrate; a channel layer comprising one or more semiconductor oxide(s); at least one gate contact layer and at least one gate insulating layer; at least one electrode contact layer comprising a metal oxide film and a metal film liner; wherein the metal oxide film is arranged between the channel layer and the metal film.

The FET as disclosed herein comprises at least one electrode contact layer in physical or electrical contact with a channel layer and a gate electrode. The gate electrode is further in contact with a gate insulating layer. The gate insulating layer may comprise at least one insulating material selected from the group consisting of silicon, silicon dioxide, and a high-k dielectric as defined herein.

In some embodiments, the FET is a dual gate FET comprising two gate contact layers and two gate insulating layers. It some other embodiments, a higher number of gate contact layers and/or gate insulating layers may be considered depending on the transistor structure.

Non-limiting suitable FET configurations within the scope of the present disclosure include planar transistors, fin FETs, and Gate-All-Around transistors.

In some embodiments, the gate insulating layer may be in electrical contact with the channel layer. In some embodiments, the gate insulating layer may be arranged between the gate electrode and the channel layer and may be in electrical contact with the gate electrode and the channel layer. In some embodiments, the gate electrode and the corresponding gate insulating layer may be disposed or positioned adjacent to or in physical contact with the channel layer, so that an external electric field can be applied to the channel, so as to modulate (and/or turn on or off) current flowing in the channel layer.

In particular embodiments, the FET as disclosed herein may comprise two electrode layers, wherein the first electrode layer and the second electrode layer are arranged at opposite sides of the gate contact layer, thereby forming a source contact layer and a drain contact layer.

In contrast to metal source contact layers and metal drain contact layers used in conventional FETs, the source contact layer and drain contact layer as described herein comprise a metal oxide film and metal film liner combination. As described above, a notable advantage of said liner combination over a (full) metal contact is that it may provide a significantly reduced contact resistance. Specifically, it has been found that the metal oxide film and metal film liner combination as disclosed herein may improve the ON current performance of a FET, without losing the ability to conduct and perform the functionalities of conventional metal contacts.

In particular embodiments, the FET as disclosed herein is characterized by an ON current (Iₒₙ) of at least 50.0 μA, such as at least 55.0 μA, or at least 60.0 μA, or at least 65.0 μA, or at least 70.0 μA, or at least 80.0 μA, or at least 90.0 μA, or at least 100.0 μA.

It is understood that any of the above embodiments relating to the method for producing the electrode contact layer comprising a metal oxide film and a metal film liner, form embodiments for the FET, and vice versa.

In particular embodiments, the substrate comprises silicon, silicon germanium, silicon oxide, gallium arsenide, gallium nitride or silicon carbide.

In particular embodiments, the semiconductor oxide is selected from the group consisting of InGaZnO, InZnO, GaZnO, Al₂O₃, Ga₂O₃, GeO₂, In₂O₃, ZnO, SnO₂, MoO₂, and mixtures thereof.

In particular embodiments, the substrate comprises a high-k dielectric film comprising an oxide selected from the group consisting of Al₂O₃, HfZrO₂, HfO₂, ZrO₂, TiO₂, HfSiO₄, and Ta₂O₅. Preferably, the high-k dielectric film is arranged between the substrate and the channel layer.

In some embodiments, the high-k dielectric film comprises a doped high-k dielectric film. In such examples, the doped high-k dielectric film can include a magnesium dopant, for example. In some embodiments, the doped high-k dielectric film comprises a magnesium-doped aluminum oxide (Al₂O₃). For example, the doped high-k dielectric film can comprise magnesium-doped aluminum oxide that contains from at least 10¹⁹ to at most 10²² magnesium atoms per cubic centimeter, or from at least 10¹⁹ to at most 10²⁰ magnesium atoms per cubic centimeter, or from at least 10²⁰ to at most 10²¹ magnesium atoms per cubic centimeter, or from at least 10²¹ to at most 10²² magnesium atoms per cubic centimeter, or from at least 10²⁰ to at most 10²² magnesium atoms per cubic centimeter. In some embodiments, the doped high-k dielectric film comprises from at least 1 atomic percent magnesium to at most 50 atomic percent magnesium. Advantageously, the magnesium doping in the aluminum oxide may block hydrogen diffusion through the magnesium-doped aluminum oxide. In some embodiments, the magnesium-doped aluminum oxide (Al₂O₃) can be subject to post deposition processes to improve the quality/properties of the doped aluminum oxide. In such examples, the magnesium-doped aluminum oxide (Al₂O₃) can be thermally treated post deposition. In one aspect, the as-deposited magnesium-doped aluminum oxide (Al₂O₃) is thermally annealed at a substrate temperature below 750° C., or below 700° C., below 650° C., below 600° C., or below 550° C., in an oxygen containing environment (e.g., O₂).

In particular embodiments, the metal oxide film comprises a metal oxide selected from the group consisting of MgO, In₂O₃, ZnO, ZnMgO, InSnO, InZnO, InMoO, V₂O₅, TiO₂, CrO₂, MnO, FeO, Fe₂O₃, CoO, NiO, Cu₂O, CuO, ZnO, ZrO₂, NbO, NbO₂, TcO₂, RuO₂, Rh₂O₃, Ag₂O, CdO, HfO₂, HfZrO, Ta₂O₅, W₂O₃, ReO₃, OsO₄, IrO₂, PtO₂, Au₂O₃, As₂O₃, Sb₂O₃, Bi₂O₃, and mixtures thereof.

In particular embodiments, the metal oxide film comprises one or more dopant(s) comprising an element selected from the group consisting of La, Pr, Nd, Pm, Sm, Eu, Gd, Tb, Dy, Ho, Er, Tm, Yb, Lu, Y, Li, Na, K, Rb, Cs, Be, Mg, Ca, Sr, Ba, Al, Ge, Sb, Te, Si, and mixtures thereof.

In particular embodiments, the metal film comprises one or more metal(s) or metalloid(s) with a work function of at least 4.0 eV, at least 4.0 eV, such as between 4.0 eV and 7.0 eV, or between 4.0 eV and 6.5 eV, or between 4.0 eV and 6.0 eV, or between 4.0 eV and 5.5 eV, or between 4.0 eV and 5.0 eV.

In particular embodiments, the metal film comprises one or more element(s) selected from the group consisting of Mg, In, V, Ti, Cr, Mn, Fe, Co, Ni, Cu, Zn, Zr, Nb, Tc, Ru, Rh, Pd, Ag, Cd, Hf, Ta, W, Re, Os, Ir, Pt, Au, As, Sb, Mo, and Bi.

In particular embodiments, the FET as disclosed herein provides that the channel layer may have an average thickness between 0.05 nm and 4.0 nm, or between 0.05 nm and 3.80 nm, or between 0.05 nm and 3.60 nm, or between 0.05 nm and 3.50 nm, or between 0.05 nm and 3.40 nm, or between 0.05 nm and 3.20 nm, or between 0.05 nm and 3.0 nm, or between 0.05 nm and 2.80 nm, or between 0.05 nm and 2.60 nm, preferably between 0.05 nm and 2.50 nm, or between 0.05 nm and 2.40 nm, or between 0.05 nm and 2.20 nm, preferably between 0.05 nm and 2.0 nm, or between 0.05 nm and 1.80 nm, or between 0.05 nm and 1.50 nm, or between 0.05 nm and 1.25 nm, or between 0.05 and 1.0 nm.

In some embodiments, the channel layer may have an average thickness of less than 1.0 nm. The thin channel as disclosed herein provides the advantage that related devices can be further scaled down and are characterized by a sharp transition between an on and off state for a flow of electrical current.

In particular embodiments, the FET as disclosed herein provides that the at least one electrode contact layer may have an average thickness between 0.05 nm and 4.0 nm, or between 0.05 nm and 3.80 nm, or between 0.05 nm and 3.60 nm, or between 0.05 nm and 3.50 nm, or between 0.05 nm and 3.40 nm, or between 0.05 nm and 3.20 nm, or between 0.05 nm and 3.0 nm, or between 0.05 nm and 2.80 nm, or between 0.05 nm and 2.60 nm, preferably between 0.05 nm and 2.50 nm, or between 0.05 nm and 2.40 nm, or between 0.05 nm and 2.20 nm, preferably between 0.05 nm and 2.0 nm, or between 0.05 nm and 1.80 nm, or between 0.05 nm and 1.50 nm, or between 0.05 nm and 1.25 nm, or between 0.05 and 1.0 nm.

In some embodiments, the at least one electrode contact layer may have an average thickness of less than 1.0 nm.

FIG. 5. illustrates an exemplary embodiment of a single gate field-effect transistor (500) of the disclosure. Said single gate transistor (500) may be formed by means of a deposition method and/or system as described herein. In the illustrated example, the single gate transistor (500) comprises a substrate (511), a channel layer (512) comprising one or more semiconductor oxide(s) as described herein positioned on the substrate (511), a gate insulating layer (513) positioned on the channel layer (512), a gate electrode (514) positioned on the gate insulating layer (513), a source contact layer (515) positioned on one end of the channel layer (512), and a drain contact layer (516) positioned on the other end of the channel layer (512). The source contact layer (515) and the drain contact layer (516) comprise a metal oxide film (517) and metal film (518) liner combination. The metal oxide film (517) is arranged between the channel layer (512) and the metal film (518).

Another aspect of the present disclosure relates to a system. The system preferably comprises: a reaction chamber constructed and arranged to hold a substrate comprising a semiconductor oxide film or a sacrificial film on at least a portion of a surface of the substrate; a first metal precursor vessel constructed and arranged to contain and evaporate one or more first metal precursor(s); an oxygen reactant vessel constructed and arranged to contain and evaporate one or more oxygen reactant(s); a second metal precursor vessel constructed and arranged to contain and evaporate one or more second metal precursor(s); a controller, operatively connected to the first metal precursor vessel, the oxygen reactant vessel, and the second metal precursor vessel; wherein the controller is configured to control the flow of the first metal precursor, the oxygen reactant, and the second metal precursor into the reaction chamber during one or more cycles, wherein, as a result of the cycles, a metal oxide film is formed on the semiconductor oxide film or the sacrificial film, and a metal film is formed on the metal oxide film.

A notable advantage of the system as disclosed herein is that it provides for a well-controlled reaction environment, which lead to more uniform and reproducible thin films or layers. In particular, the controller can be configured to adjust the flow rate and timing to optimize the reaction kinetics, thereby providing a metal oxide film and metal film with a desired composition and thickness.

In particular embodiments, the system as disclosed herein is configured to form an electrode layer comprising a metal oxide film and a metal film liner by means of a method as disclosed herein.

It is understood that any of the above embodiments relating to the method for producing the electrode layer comprising a metal oxide film and a metal film liner, form embodiments for the system, and vice versa.

In particular embodiments, at least a part of the sacrificial film may be removed in the system as disclosed herein.

In particular embodiments, the system may further comprise a semiconductor oxide vessel constructed and arranged to contain and evaporate one or more semiconductor oxide(s), wherein the controller is further configured to control the flow of the semiconductor oxide into the reaction chamber during one or more cycles, and wherein, as a result of the cycles, a semiconductor oxide film is formed on the substrate or in at least a part of the space from which the sacrificial film can be removed.

In particular embodiments, the system may further comprise a dopant vessel constructed and arranged to contain and evaporate one or more dopant(s), wherein the controller is further configured to control the flow of the dopant into the reaction chamber during one or more cycles.

In some embodiments, the one or more first metal precursor(s), the one or more second metal precursor(s), the one or more oxygen reactant(s), the optional one or more dopant(s), and optional one or more semiconductor oxide precursor(s) is provided to the reaction chamber from a temperature-controlled vessel. In some embodiments, the temperature-controlled vessel is configured for cooling the precursors, dopants and/or reactants. In some embodiments, the temperature-controlled vessel is configured for heating the precursors, dopants and/or reactants. In some embodiments, the temperature-controlled vessel is maintained at a temperature of at least −50° C. to at most 20° C., or at a temperature of at least 20° C. to at most 250° C., or at a temperature of at least 100° C. to at most 200° C.

In particular embodiments, the system as disclosed herein may be configured to manufacture a semiconductor device as disclosed herein or a field-effect transistor (FET) as disclosed herein.

In particular embodiments, the system as disclosed herein is configured for forming at least a portion of a semiconductor device as disclosed herein or a field-effect transistor (FET) as disclosed herein.

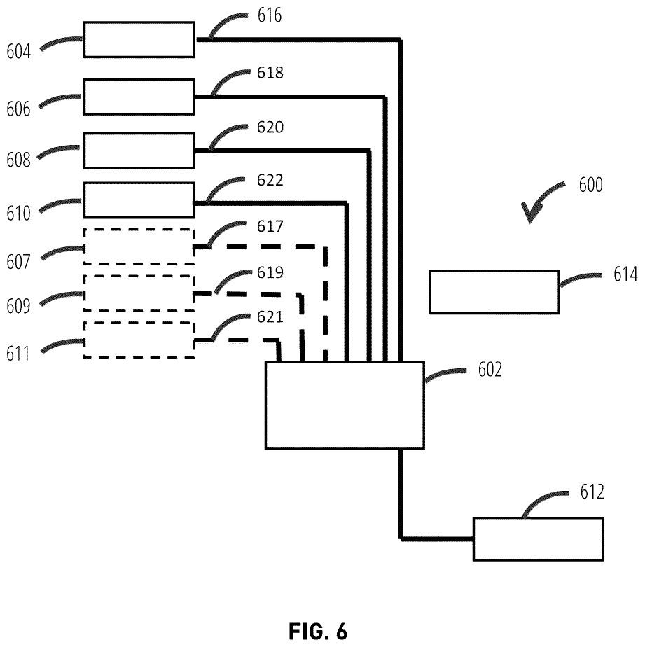

FIG. 6. schematically illustrates a system (600) in accordance with yet additional exemplary embodiments of the disclosure. The system (600) can be used to perform a method as described herein and/or form a (portion of) a transistor or semiconductor device as described herein.

In the illustrated example, the system (600) includes one or more reaction chambers (602), a first metal precursor gas source (604), a second metal precursor gas source (606), an oxygen reactant source (608), a purge gas source (610), an exhaust (612), and a controller (614).

The reaction chamber (602) can include any suitable reaction chamber, such as an ALD or CVD reaction chamber. Optionally, the system (600) comprises further gas sources such as a dopant gas source (607), a semiconductor oxide gas source (609) and a vacuum power source (611).

The first metal precursor gas source (604) can include a vessel, and one or more first metal precursors as described herein-alone or mixed with one or more carrier (e.g., inert) gases. The second metal precursor gas source (606) can include a vessel and one or more second metal precursors as described herein-alone or mixed with one or more carrier (e.g., inert) gases. The oxygen reactant source (608) can include a vessel, and one or more oxygen reactants as described herein-alone or mixed with one or more carrier (e.g., inert) gases. The purge gas source (610) can include one or more inert gases such as N₂ or a noble gas, as described herein. The system (600) can include any suitable number of gas sources. The gas sources (604)-(611) can be coupled to reaction chamber (602) via lines (616)-(621), which can each include flow controllers, valves, heaters, and the like. The exhaust (612) can include one or more vacuum pumps.

The controller (614) includes electronic circuitry and software to selectively operate valves, manifolds, heaters, pumps, and other components included in the system (600). Such circuitry and components operate to introduce precursors, reactants, optional dopants, and purge gases from the respective sources (604)-(611). The controller (614) can control timing of gas pulse sequences, temperature of the substrate and/or reaction chamber, pressure within the reaction chamber, and various other operations to provide proper operation of the system (600). The controller (614) can include control software to electrically or pneumatically control valves to control flow of precursors, optional dopants, reactants and purge gases into and out of the reaction chamber (602). The controller (614) can include modules such as a software or hardware component, e.g., a FPGA or ASIC, which performs certain tasks. A module can advantageously be configured to reside on the addressable storage medium of the control system and be configured to execute one or more processes.

Other configurations of the system (600) are possible, including different numbers and kinds of precursor and reactant sources, optional dopant sources, and purge gas sources. Further, it will be appreciated that there are many arrangements of valves, conduits, precursor sources, reactant sources, optional dopant sources, and purge gas sources that may be used to accomplish the goal of selectively feeding gases into the reaction chamber (602). Further, as a schematic representation of a system, many components have been omitted for simplicity of illustration, and such components may include, for example, various valves, manifolds, purifiers, heaters, containers, vents, and/or bypasses.

In addition, embodiments of the controller may include a combination of hardware, software, and electronic components or modules that, for purposes of discussion, may be portrayed as if primarily implemented in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits.

During operation of the reactor system (600), substrates, such as semiconductor wafers (not illustrated), are transferred from, e.g., a substrate handling system to reaction chamber (602). Once substrate(s) are transferred to the reaction chamber (602), one or more gases from the gas sources (604)-(611), such as precursors, reactants, carrier gases, optional dopants, and/or purge gases, are introduced into reaction chamber (602).

The subject matter of the present disclosure includes all novel and nonobvious combinations and subcombinations of the various processes, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

1. Method for forming an electrode contact layer comprising a metal oxide film and a metal film liner, the method comprising the steps of:
a) providing a substrate into a reaction chamber, wherein the substrate comprises a semiconductor oxide film on at least a portion of a surface of the substrate;
b) executing one or more cycles, each cycle comprising:
i. a first metal precursor pulse, wherein at least a part of the semiconductor oxide film is contacted with one or more first metal precursors, by introducing the first metal precursor into the reaction chamber; and
ii. an oxygen reactant pulse, wherein at least a part of the semiconductor oxide film is contacted with one or more oxygen reactants, by introducing the oxygen reactant into the reaction chamber,
thereby forming the metal oxide film on the semiconductor oxide film; and
c) executing one or more further cycles, each further cycle comprising:
a second metal precursor pulse, wherein at least a part of the metal oxide film is contacted with one or more second metal precursors, by introducing the second metal precursor into the reaction chamber,
thereby forming the metal film liner on the metal oxide film.

2. The method according to claim 1, wherein the semiconductor oxide film comprises a semiconductor oxide selected from the group consisting of InGaZnO, InZnO, GaZnO, Al₂O₃, Ga₂O₃, GeO₂, In₂O₃, ZnO, SnO₂, MoO₂, and mixtures thereof.

3. The method according to claim 2, wherein the semiconductor oxide film consists of InGaZnO, wherein the IGZO has about 0.1:1:1 to 10:1:1 stoichiometry of ratio of elements In:Ga:Zn.

4. The method according to claim 1, wherein the semiconductor oxide film comprises a dopant element selected from the group consisting of Ce, Pr, Nd, Pm, Sm, Eu, Gd, Tb, Dy, Ho, Er, Tm, Yb, Lu, Y, Li, Na, K, and mixtures thereof.

5. The method according to claim 1, wherein the first metal precursor comprises an element selected from the group consisting of Mg, In, V, Ti, Cr, Mn, Fe, Co, Ni, Cu, Zn, Zr, Nb, Tc, Ru, Rh, Pd, Ag, Cd, Hf, Ta, W, Re, Os, Ir, Pt, Au, As, Sb, Mo, and Bi.

6. The method according to claim 1, wherein the metal oxide film comprises a metal oxide selected from the group consisting of MgO, In₂O₃, ZnO, ZnMgO, InSnO, InZnO, InMoO, V₂O₅, TiO₂, CrO₂, MnO, FeO, Fe₂O₃, CoO, NiO, Cu₂O, CuO, ZnO, ZrO₂, NbO, NbO₂, TcO₂, RuO₂, Rh₂O₃, Ag₂O, CdO, HfO₂, HfZrO, Ta₂O₅, W₂O₃, ReO₃, OsO₄, IrO₂, PtO₂, Au₂O₃, As₂O₃, Sb₂O₃, Bi₂O₃, and mixtures thereof.

7. The method according to claim 1, wherein step b) further comprises:
iii. a dopant pulse, wherein at least a part of the semiconductor oxide film is contacted with one or more dopants, by introducing the dopant in the reaction chamber.

8. The method according to claim 7, wherein the dopant comprises an element selected from the group consisting of La, Pr, Nd, Pm, Sm, Eu, Gd, Tb, Dy, Ho, Er, Tm, Yb, Lu, Y, Li, Na, K, Rb, Cs, Be, Mg, Ca, Sr, Ba, Al, Ge, Sb, Te, Si, and mixtures thereof.

9. The method according to claim 1, wherein the metal film liner comprises one or more metals or metalloids with a work function of at least 4.0 eV.

10. The method according to claim 1, wherein the second metal precursor comprises an element selected from the group consisting of Mg, In, V, Ti, Cr, Mn, Fe, Co, Ni, Cu, Zn, Zr, Nb, Tc, Ru, Rh, Pd, Ag, Cd, Hf, Ta, W, Re, Os, Ir, Pt, Au, As, Sb, Mo, and Bi.

11. The method according to claim 1, wherein the oxygen reactant is selected from the group consisting of H₂O, H₂O₂, O₃, O₂, O-containing plasma, N₂O, NO, N₂O₅, and oxygen radicals.

12. The method according to claim 1, wherein the method is an atomic layer deposition (ALD) method.

13. The method according to claim 1, wherein the substrate further comprises a high-k layer arranged between the semiconductor oxide film or sacrificial film and the formed metal oxide film.

14. The method according to claim 13, wherein the high-k layer comprises an oxide selected from the group consisting of Al₂O₃, HfZrO₂, HfO₂, ZrO₂, TiO₂, HfSiO₄, and Ta₂O₅.

15. The method according to claim 1, wherein the substrate comprises silicon, silicon germanium, silicon oxide, gallium arsenide, gallium nitride or silicon carbide.

16. The method according to claim 1, wherein the substrate is heated in said reaction chamber to a temperature between 80° C. and 400° C.

17. The method according to claim 1, wherein the pressure in the reaction chamber is between about 0.1 Torr and about 100.0 Torr.

18. The method according to claim 1, wherein the electrode contact layer comprising the metal oxide film and the metal film liner is formed without any intervening vacuum break.

19. The method according to claim 1, wherein the substrate further comprises a sacrificial film.

20. The method according to claim 19, further comprising the steps of removing at least a part of the sacrificial film, thereby forming a cavity, and forming the semiconductor oxide film in the cavity, wherein the step of removing at least a part of the sacrificial film comprises etching the sacrificial film.
